(19) United States
(12) Patent Application Publication
(10) Pub. No.: US 2011/0150568 A1
(43) Pub. Date: Jun. 23, 2011

(54) WEDGE-TYPE LOCKING DEVICE

(76) Inventor: Guenter Deisenhofer, Bobingen (DE)

(21) Appl. No.: 12/663,922

(22) PCT Filed: May 21, 2008
(86) PCT No.: PCT/US08/64293

§ 371 Date: Jan. 31, 2011

(30) Foreign Application Priority Data
Jun. 14, 2007 (DE) 10 2007 028 043.4

(51) Int. Cl. F16B 2/14; H05K 7/14

(52) U.S. Cl. 403/374.3; 403/373; 403/374.1

(57) ABSTRACT

A clamping device (10) is configured to apply opposite clamping forces in both a first (x-axis) and second (z-axis) traverse direction when being compressed in a longitudinal direction (y-axis) to fix elements to another. The device includes clamping means able to transform compressive movements and/or forces in said longitudinal direction into expanding movements and/or forces in both said traverse directions until the expansion is stopped by abutment in said traverse directions upon adjacent elements for application of clamping forces. Additionally, the compressive force used to generate the clamping forces in both said traverse directions allows for attaching the device to a support for fixing an element in all three directions by one single manual operating action.

### BACKGROUND OF THE INVENTION

The present invention generally relates to locking devices and more particularly to wedge-type locking devices for fixing elements which may be subjected to vibrations and shocks to one another. A heavy-weight chassis containing electronic equipment of an aircraft can be affixed to a frame or tray by a wedge-type locking device during a flight, for example.

### DESCRIPTION OF THE PRIOR ART

Wedge-type locking devices for joining elements to one another are known in the art. U.S. Pat. No. 3,971,186 discloses a wedge-type lock comprising five blocks aligned to one another and each providing a trapezoidal cross-section. The outwardmost blocks can be forced towards one another by rotating a screw engaging same and extending in a through hole within all of the blocks. Sloped gliding surfaces between adjacent blocks make the blocks slide along the surfaces and move in upward and downward directions in relation to one another while being compressed by a compressive force generated by rotating the screw. The line of blocks is located within a slot defined by two parallel flanges of a first element and coupled to one of said flanges.

For operating the prior art wedge-type lock, a flange of a second element to be affixed to said first element is inserted into the remaining portion of the slot and clamped between the second flange of the first element and two of the blocks, when the slot is narrowed by tightening the screw. Accordingly, the first and second elements can be separated after releasing the screw.

Although such wedge-type locking devices often provide a suitable effectiveness, the clamping action may not be satisfactory because the flanges rely on frictional forces to be held in place laterally. In particular, if the device is subjected to vibrations or shocks, the clamping effect may not be sufficient. Furthermore, the flange of the second element has to be positioned at its desired target location within the gap manually before tightening the screw.

The present invention is directed to an improved wedge-type locking device which is able to fix an element in two or even three dimensions by applying clamping forces at its surfaces instead of relying on frictional forces. Furthermore, it is an object of the present invention to provide a wedge-type lock which is able to fix an element in a predefined position in relation to another element without requiring a manual alignment of said element.

### SUMMARY OF THE INVENTION

The present invention provides a clamping means which is expandable in two distinct directions when being compressed in a third direction. The clamping means includes a compression means for compressing said clamping means in a longitudinal direction to expand the clamping means in both a first and second traverse directions to make the clamping means apply clamping forces in both said first and second traverse directions. According to the present invention, said longitudinal and first and second traverse directions are neither collinear nor coplanar, but linearly independent directions.

The clamping means according to the present invention can be part of a clamping fixture used to fix a moveable element, e.g. a chassis, to a fixed element, e.g. a tray. The clamping means may be located between a first wall of the fixed element and a first wall of the moveable element in said first traverse direction. The clamping means is configured to apply clamping forces to said fixed element first wall and said moveable element first wall in said first traverse direction by abutting upon said walls in reaction to an expansion of the clamping means in the first traverse direction caused by a compression of said clamping means in said longitudinal direction. Thus, a fixation in said first traverse direction is attained.

In a preferred embodiment of the present invention the clamping means is mounted to said moveable element and located in the second traverse direction between a second wall of the fixed element and an abutment element joined to the fixed element. The clamping means is configured to apply a clamping force in said second traverse direction to said abutment element by abutting upon same. The clamping means is further configured to make itself or the moveable element to which it is mounted abut upon and apply a clamping force in said second traverse direction to said fixed element second wall. Thus, a fixation in said second traverse direction is attained.

Additionally, in a further preferred embodiment the compression means engages a third wall of the said fixed element and is configured for fixing said clamping means to said third wall in said longitudinal direction when compressing said clamping means. The engaged third wall of the fixed element may be compressed along with said clamping means. This preferred embodiment of the present invention allows fixing said moveable element to said fixed element in said longitudinal direction as well which leads to a fixation in all three dimensions.

In an alternate embodiment of the present invention the clamping means can be affixed to the fixed element. It may be located next to an abutment element joined to said moveable element. The clamping means may abut upon and apply a clamping force in said second traverse direction to said abutment element to urge said moveable element to a second wall of said fixed element. The clamping means may transmit the counterforce to the fixed element to which it is affixed. Thus, a fixation in said second traverse direction is attained in an alternate manner.

Preferably, said longitudinal direction and said first traverse direction are orthogonal. Preferably, said longitudinal direction and said second traverse direction are orthogonal. In other words, in a preferred embodiment the direction of compression and each one of the directions of expansion define a right angle. Nevertheless, it is possible to provide angles different from 90°. Such an expanding movement would include a superposition of an orthogonal expansion along with a longitudinal shift of the clamping means in reaction to the longitudinal compression.

Preferably, said first and second traverse directions are orthogonal. Therefore, both directions of expansion define a right angle, while a different angle may be chosen as well. In a preferred embodiment, any two of said longitudinal, first and second traverse directions are orthogonal. In other words, the longitudinal and first and second traverse directions define a Cartesian coordinate system. Nevertheless, any other combinations wherein each two of the three directions either define a right angle or not, are taken into consideration as well.

In one embodiment of the present invention the clamping means includes a deformable material which is able to expand by a significant amount in both a first and second traverse directions to apply clamping forces to adjacent elements, when being compressed in a longitudinal direction. Said deformable material can include a rubber element, for example. Alternatively, said deformable material can include a fluid enclosed in an suitable envelope. The fluid is able to generate forces in traverse directions in reaction to a compression in said longitudinal direction by means of its static pressure.

In a preferred embodiment of the present invention the clamping means is part of a wedge-type locking device, wherein the clamping means includes at least two wedge elements aligned to each other in said longitudinal direction. Each one of said wedge elements provides at least one gliding surface facing in said longitudinal direction and mating with an opposite gliding surface of an adjacent one of said wedge elements to allow a sliding movement of the adjacent wedge elements in relation to one another.

Said compression means includes means for forcing said first and second wedge elements towards one another. Thus a compressive force in said longitudinal direction can be applied to the gliding surfaces between said first and second and any further wedge elements located in between. At least two gliding surfaces of adjacent wedge elements mating with each other are sloped such that a compressive force applied to the wedge elements in said longitudinal direction is transmitted into forces in traverse direction by a sliding movement along said gliding surface. Said forces urge at least two of said wedge elements in said first traverse direction in relation to one another and at least two of said wedge elements, which may be the same or other ones of said wedge elements, in said second traverse direction in relation to one another, when said first and second wedge elements are forced towards one another. Thus, the range of wedge elements may be expanded in said traverse directions while being shortened in said longitudinal direction.

In a preferred embodiment the wedge-type locking device according to the present invention provides at least one gliding surface which is sloped in both said first and second traverse directions to transform a compressive force in said longitudinal direction into clamping forces in both said first and second traverse directions. In other words and referring to longitudinal and first and second traverse directions defining said preferred Cartesian coordinate system, the normal vector of the gliding surface may extend in a triagonal direction, i.e. none of its three components equals zero. A gliding surface sloped in this way allows for urging wedge elements in relation to one another in both said first and second traverse directions when sliding along said gliding surface in reaction to a longitudinal compressive force.

In a another embodiment the wedge-type lock can include at least a first gliding surface being sloped in said first traverse direction for generating clamping forces in said first traverse direction in reaction to a compressive force in said longitudinal direction. Furthermore, the inventive device can comprise at least a second gliding surface being sloped in that second traverse direction for urging at least two of said wedge-elements in said second traverse direction in relation to one another for applying clamping forces. The wedge-type locking device may provide distinct sections oriented for applying clamping forces in either said first or said second traverse directions to distinct pairs of wedge elements. Alternatively, the gliding surfaces sloped in either said first or said second directions can be arranged in an alternating or any other order.

According to the present invention, the slope of said gliding surfaces can be chosen based on the materials of the wedge elements, which are preferably made of metal. The coefficients of static or dynamic friction, the desired amounts of expansion in said first and second traverse directions and the amount of compression available in said longitudinal direction have to be taken into account when designing the gliding surfaces. The tangent function of the slope angle defines a compression to expansion ratio. Anyway, the slope must be sufficient to overcome the static friction at the gliding surface, while still providing sufficient clamping forces in said traverse directions.

With regard to the preferred gliding surfaces sloped in both said first and second traverse directions, the different directions of a sliding movement along the gliding surfaces have to be taken into account as well. The relative movement of the adjacent wedge elements in reaction to said compressive force need not follow the maximum gradient of said sliding surface automatically, but may be influenced by other factor such as the weight of an individual wedge element. Furthermore, after the traverse expansion of the wedge-type locking device has lead to an abutment of a wedge element in one of said first and second traverse directions, the traverse movement of said wedge element in reaction to further compression may continue, but will be restricted to the other (or free) one of said traverse directions.

The relative movement of adjacent wedge elements along said gliding surface may now align with said other traverse direction leading to a reduced slope compared to the maximum slope direction of said gliding surface. Furthermore, after abutment in one traverse direction has occurred, a wedge element may slide along the surface it has abutted upon in reaction to further compression causing additional friction. Finally, abutment occurs in the other one of said first and second traverse directions as well to fix the element in its clamping position. All these frictional forces have to be overcome by choosing a sufficient slope of said gliding surface.

In a preferred embodiment of the wedge-type locking device according to the present invention said compression means includes a tightening screw for transmitting a pulling force to urge both said first and second wedge elements towards one another. Said pulling force may be generated by rotating said tightening screw and balanced by the compressive force applied to said wedge elements.

Preferably, said tightening screw is received within a through hole extending substantially in said longitudinal directions within at least one of said wedge elements. Preferably, the through hole extends within said first and second and any other wedge elements to be subjected to compression. The compressive force may be applied from the tightening screw to outwardly facing surfaces of said first and second wedge elements by means of a laterally protruding head section, a nut, a washer or any other means known in the art. In one embodiment, a tightening screw including a male thread section may be integrally coupled to one of the wedge elements and configured for engaging a nut for applying a compressive force to wedge elements located in between. In a complementary embodiment, one wedge element may provide a female thread section for engaging a tightening screw bolt. In a preferred embodiment, the tightening screw is not coupled to any of said wedge elements integrally.

Preferably, said through holes within said wedge elements are sized to provide a clearance to allow a movement of said wedge elements in said longitudinal direction in relation to the tightening screw when the device is compressed longitudinally. The cross-sectional area of said through hole may be configured to allow ready displacement of said wedge elements in longitudinal direction without allowing for a significant displacement in any traverse direction. The cross-section may be circular.

Alternatively, the cross-sectional area of said through hole may be configured to allow ready displacement of said wedge elements in said longitudinal and first traverse directions without allowing for a significant displacement in said second traverse directions. The cross-section may be oval-shaped. In another embodiment, the cross-sectional area of said through hole may be configured to allow ready displacement of said wedge elements in said longitudinal and second traverse directions without allowing for a significant displacement in said first traverse directions. The cross-section may also be oval-shaped. In a preferred embodiment, at least one wedge element provides a through hole having a cross-sectional area configured to allow a ready displacement of said wedge elements in said longitudinal and first and second traverse directions. The cross-section may be circular and providing a diameter significantly larger than the diameter of said tightening screw. It may have any other shape allowing for independent displacements of said wedge element in both said first and second traverse directions.

Preferably, the remaining portions of said gliding surfaces around the through holes are sufficient to allow any gliding movements and transmission of the forces which can occur in any feasible arrangements, i.e. within the reach of said wedge elements restricted by the clearance of said wedge elements in relation to said tightening screw. In a preferred embodiment, the through holes are sized such that the wedge elements are not weakened excessively, while the reach of the expansion in both said first and second traverse direction is sufficient to bridge a gap for the desired clamping operation, for example.

In a preferred embodiment the tightening screw provides an operating means configured to allow manually tightening and releasing said tightening screw. Preferably, the operating means is able to maintain its setting after the operation thereof. The operating means can be a self-locking hand knob.

In a preferred embodiment of the wedge-type locking device according to the present invention, at least one of said wedge elements is mounted to a chassis to be fixed to a tray. The wedge-type lock is located between a first wall of the chassis and a first wall of the tray in said first traverse direction. The wedge-type lock is configured to apply clamping forces to said chassis first wall and said tray first wall in said first traverse direction by making at least one wedge element abut upon each one of said walls in reaction to an expansion of the wedge-type lock in said first traverse direction caused by a compression of said device in said longitudinal direction. Thus, a fixation in said first traverse direction is attained.

Preferably, said wedge-type locking device is located between a second wall of the tray and an abutment element joined to the tray. The wedge-type lock is configured to apply a clamping force in said second traverse direction to said abutment element by making at least one wedge element abut upon same. The wedge-type lock is further configured to make itself or the chassis to which it is mounted abut upon and apply a clamping force in said second traverse direction to said second wall of said tray. Thus, a fixation in said second traverse direction is attained.

Additionally, in a further preferred embodiment the tightening screw engages a third wall of the said tray and is configured for fixing said wedge-type locking device to said third wall in said longitudinal direction when compressing said wedge-type lock. The engaged third wall of the tray may be subjected to compression along with said wedge elements and fixed thereto by tightening the screw. Thus, the preferred embodiment of the present invention allows fixing said chassis to said tray in said longitudinal direction as well which leads to a fixation in all three dimensions.

In an alternate embodiment of the present invention at least one of said wedge elements can be mounted to the tray. It may be located next to an abutment element joined to said chassis. The device is configured to make at least one wedge element abut upon and apply a clamping force in said second traverse direction to said abutment element to urge said chassis to a second wall of said tray. The wedge-type lock may transmit the counterforce to the tray to which it is affixed. Thus, a fixation in said second traverse direction is attained in an alternate manner.

### BRIEF DESCRIPTION OF THE DRAWINGS

The present invention will be better understood by reading the following description in conjunction with the attached drawings wherein:

FIG. 1 is a perspective view of a chassis including a wedge-type locking device in accordance with the teachings of the present invention;

FIG. 2 is an enlarged perspective view of a portion of a single wedge element of FIG. 1;

FIG. 3 is an enlarged perspective view of a portion of another wedge element show in of FIG. 1;

FIG. 4 is a schematic illustration of a top view of a portion of the wedge-type locking device shown in FIG. 1 in a compressed position;

FIG. 5 is a schematic illustration of a top view of the wedge-type locking device shown in FIG. 1 in the extended position depicting the application of compressive forces to the wedge elements and the resulting movements of the individual wedge elements;

FIG. 6 is a side elevational view of the device shown in FIG. 5;

FIG. 7 is a top view similar to FIG. 5 of an alternate embodiment of the wedge-type locking device;

FIG. 8 is a side elevational view of the device shown in FIG. 7;

FIG. 9 is a perspective view of a tightening screw according to the present invention;

FIG. 10 is a cross-sectional view of the chassis, the tray and the wedge-type locking device according to a preferred embodiment of the present invention;

FIG. 11 is a cross-sectional view similar to FIG. 10 of an alternate embodiment of the present invention.

FIG. 12 is a cross-sectional view of a preferred embodiment of the present invention similar to the device shown in FIG. 10.

FIG. 13 is another cross-sectional view of the device shown in FIG. 12.

### DETAILED DESCRIPTION OF THE INVENTION

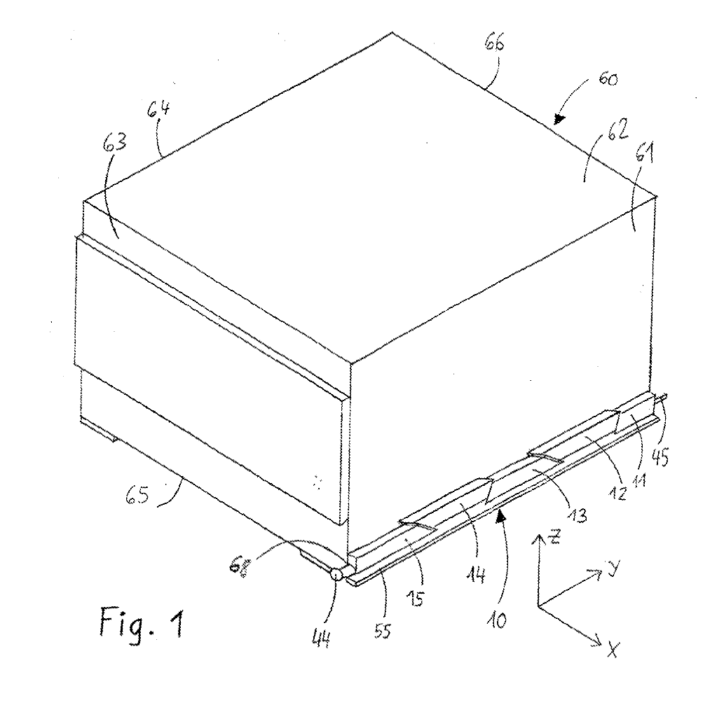

With reference now to the drawings, FIG. 1 shows an perspective overview of a preferred embodiment of the present invention including a rectangular block-shaped chassis 60. The chassis contains electronic equipment of an aircraft (not shown) to be fixed to a tray providing a recess for securing during a flight. The chassis 60 provides a right-hand wall 61, a top wall 62, a forward wall 63, a left-hand wall 64, a bottom wall 65 and a rear wall 66. The tray surrounds the lower part of the chassis for preventing lateral movements of the chassis while a clearance is left to allow handling the chassis and inserting it into or removing it out of the tray. The tray further comprises a bottom wall 55, only a part of which is shown in FIG. 1. A wedge-type locking device 10 in accordance with the present invention is affixed to and extending along a lower edge 68 of the right-hand wall 61 of said chassis 60.

Now reference is made to a Cartesian coordinate system used for convenience throughout the drawings and the detailed description to illustrate the orientation of the embodiments of the present invention. As shown in FIG. 1, the x axis extends in from the left to the right, the y axis extends from the front to the back and the z axis extends from the bottom to the top. The views depicted in the following drawings refer to this coordinate system. According to this embodiment, the y axis corresponds to said longitudinal direction, the x axis corresponds to said first traverse direction and the z axis corresponds to said second traverse direction. As mentioned above, an orthogonal system is preferred and used throughout the drawings and the description. Nevertheless, it has to be understood that other embodiments of the present invention could be implemented, wherein one or more angles defined by any two of the three axes do not equal 90 degrees.

A clamping means according to the present invention includes a wedge-type locking device 10 including a first, second, third, forth and fifth wedge elements 11, 12, 13, 14, 15 aligned in the y direction along said lower edge 68. The wedge locking device which is shown in more detail in the following figures further includes a tightening screw 41 extending in the y direction. The tightening screw projects out of the first wedge element 11. A hand knob 44 for manually rotating the tightening screw is attached to the forward end of the screw 41.

A threaded section 45 of the tightening screw 41 is engaging a nut (not shown in FIG. 1) for applying a pressure force between said hand knob 44 located at the forward end and the nut located at the rear end of the tightening screw 41. Said force compresses the range of wedge elements 11, 12, 13, 14, 15 made of metal to cause a compression of said wedge-type locking device 10 in y direction along with an expansion thereof in both x and z directions. The structure and the operation of the element of the wedge-type locking device 10 are now explained in detail with reference to the following drawings.

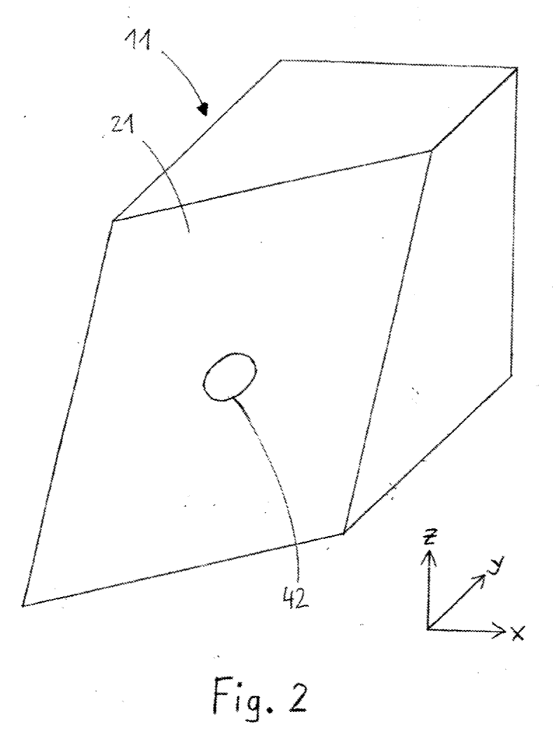

FIG. 2 shows a perspective view of a forward portion of the wedge element 11 shown in FIG. 1. The wedge element provides a substantially rectangular block shape. However, the forward surface provides a gliding surface 21 facing the adjacent wedge element 12 shown in FIG. 1, which is angled with regard to both said x and z directions. In other words, said gliding surface 21 provides a surface normal extending in a triagonal direction, i.e. none of the x, y and z components of the surface normal vector equals zero.

The wedge elements 11, 13, 15 provide a central cylindrical through bore extending in the y direction. The through hole 42 is configured to receive the tightening screw 41 with little clearance just to allow free turning and axially displacing the tightening screw while substantially preventing any lateral movements thereof. Therefore, the tightening screw fixes the wedge elements 11, 13 and 15 in line.

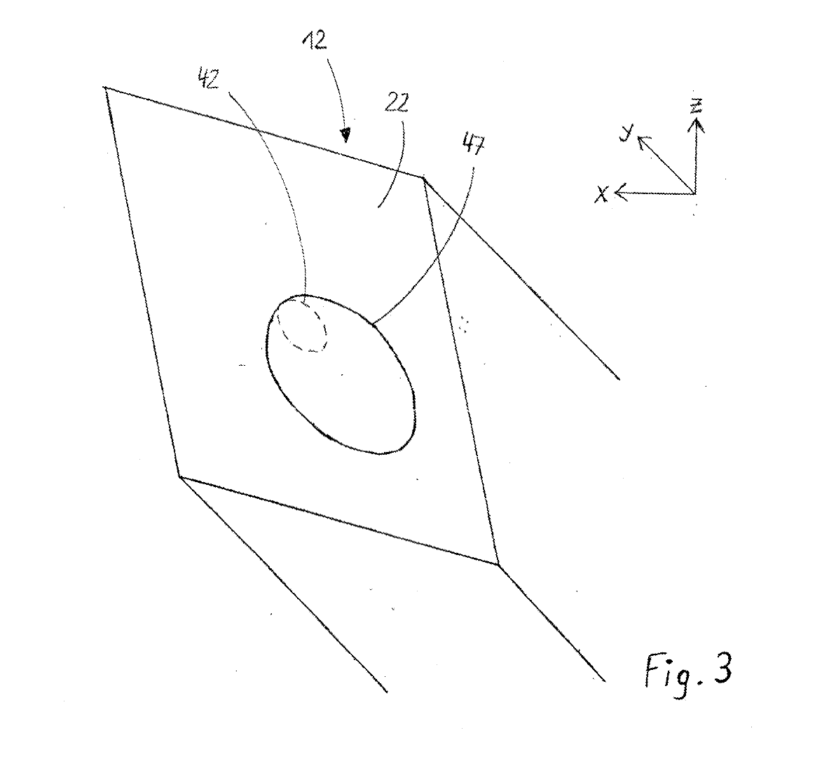

FIG. 3 shows a backside perspective view of the rear end of the wedge element 12 which is a metal block similar to the wedge element 11 also providing the same rectangular cross-section. The wedge element 12 provides a gliding surface 22 parallel to and contacting said gliding surface 21 of said wedge element 11. Each one of the wedge elements 12 and 14 provides a cylindrical through hole 47 having three times the diameter of said through hole 42 and extending in the y direction for receiving the tightening screw 41 as well. Therefore, a considerable clearance to allow for lateral movements of the wedge element 12 and 14 in the x and z directions in relation to the tightening screw 41 and the wedge elements 11, 13 and 15 aligned therewith is provided.

The intersection of the through hole 47 and the gliding surface 22 is indicated as a solid ellipse in FIG. 3 while the dashed ellipse in the center of the gliding surface 22 indicates the intersection of the tightening screw 41 and the gliding surface 22 when the outer surfaces of the wedge elements 11 and 12 are aligned to another. As shown in FIG. 3, the through hole 47 extends beyond the tightening screw 41 substantially in both negative x and negative z directions. Thus, the wedge elements 12 and 14 can be displaced substantially in positive x and/or positive z directions in relation to the tightening screw 41 and the wedge elements 11, 13 and 15, as shown in FIG. 1. One skilled in the art will understand that the sizes and shapes of the through holes 42, 47 and the diameter of the tightening screw 41 define the reach of the individual wedge element in x and z directions. They are given as an example. Any other configurations allowing for a sufficient displacement of the wedge elements, leaving a sufficient remnant of the gliding surface and keeping the integrity and durability of the wedge element can be chosen instead.

The slope of the gliding surfaces 21 and 22 is sufficient to transform a compressive force in the y direction applied by said tightening screw 41 to the gliding surfaces 21 and 22 of the adjacent wedge elements 11 and 12 into a movement of the wedge elements in x and/or z directions in relation to one another in reaction to said compressive force.

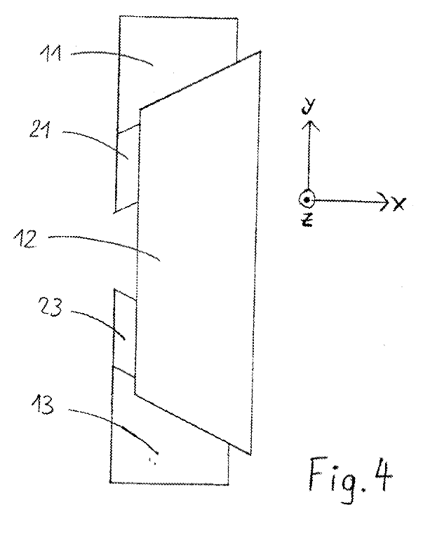

FIG. 4 shows a schematic illustration of a top view of a rear portion of the wedge-type locking device 10 shown in FIG. 1. The second wedge element 12 has been displaced in relation to the first and third wedge elements 11 and 13 in both positive x and positive z directions by sliding along the gliding surface 21 of the first wedge elements 11, as described above, and along a corresponding gliding surface 23 of the third wedge element 13 providing an opposite slope.

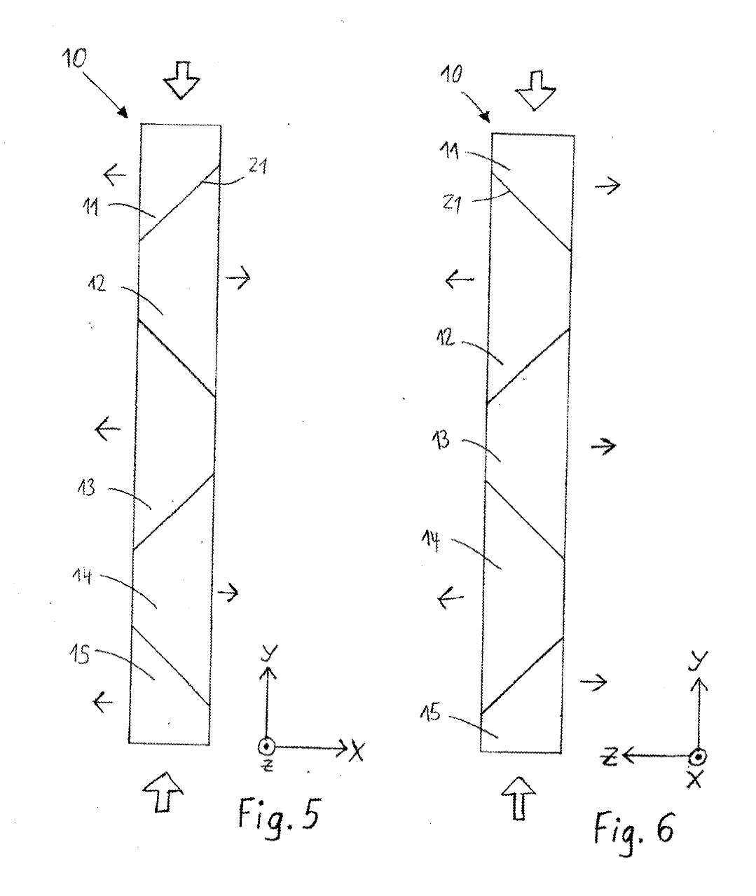

The FIGS. 5 and 6 show schematic illustrations of a top view and a side elevation view of the range of wedge elements of the wedge-type locking device 10 shown in FIG. 1, respectively. The large arrows represent the compressive force applied to the outer wedge elements 11 and 15 by the compression means. The small arrows represent the resulting movements of the wedge elements and the clamping forces they may apply to adjacent elements. If a wedge-type locking device 10 is fixed to the chassis as shown in FIG. 1, the first, third and fifth wedge elements 11, 13 and 15 cannot move in x and z directions while the second and fourth wedge elements 12 and 14 will move in both positive x and positive z direction. Other configurations can be implemented as well depending on the movability of the individual wedge elements in relation to the tightening screw.

Since the x and z shifts of each one of said second and forth wedge elements 12 and 14 can occur independently and independent from the displacement of the other one of said wedge elements 12 and 14, the system provides four degrees of freedom. If one of the wedge elements 12 or 14 abuts upon a surface (not shown) in one of the x and z directions, the movement of the wedge element in the other one of the x and z directions can continue by a sliding movement of the wedge element along the abutment surface until the wedge element abuts in the second direction as well. The displacement of the other one of said second and fourth wedge elements 12 and 14 in reaction to the compressive force can continue independently.

When both said second and forth wedge elements 12 and 14 have abutted in both x and z directions, a further expansion of the wedge-type locking device 10 is not possible any more in neither x nor z direction, and the compression in the y direction is blocked. The longitudinal compressive force applied by the tightening screw 41 is now transformed into traverse forces in x and z directions applied by the wedge elements for achieving the clamping effect.

A self-locking hand knob 44 which is used to operate the tightening screw 41 will fix the locking device 10 in the locked position. Additionally, a spring element (not shown) compressed in series with the wedge elements can be used to maintain the compressive force after the operation of the hand knob 44 has been stopped and the device may be subjected to vibrations or shocks.

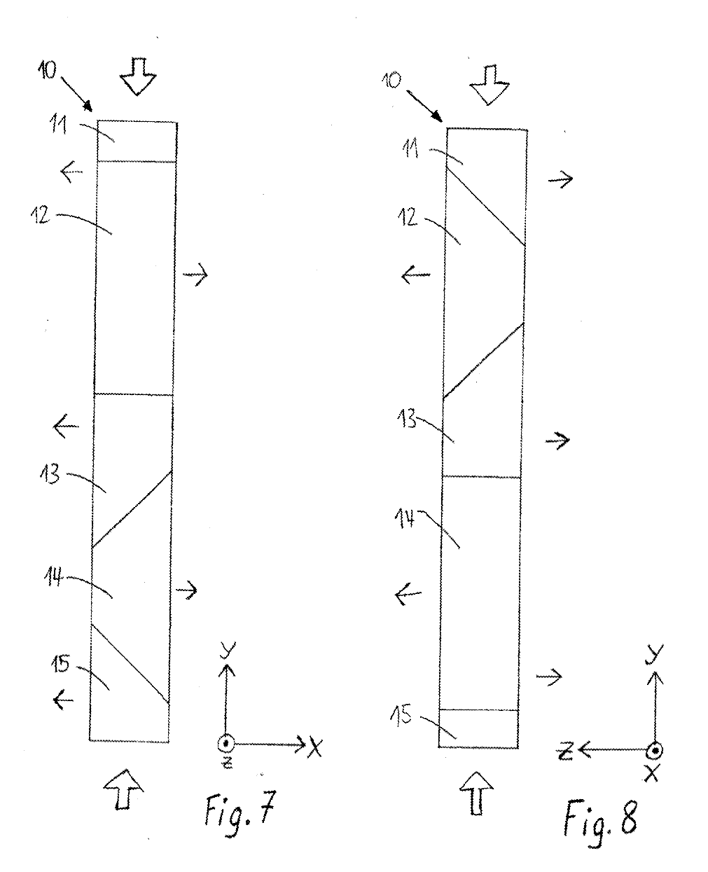

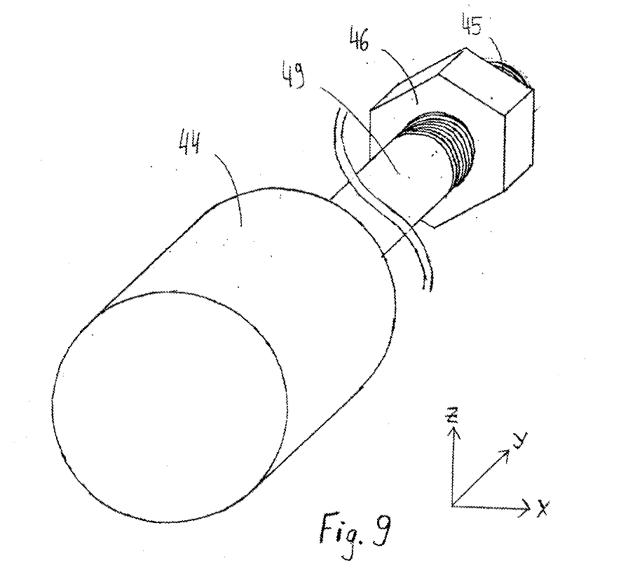

The FIGS. 7 and 8 show schematic illustrations of a top view and a side elevational view of the range of wedge elements of the wedge-type locking device 10 of an alternate embodiment. The FIGS. 7 and 8 are similar to the FIGS. 5 and 6, respectively. According to this embodiment of the present invention, the wedge elements 12 and 14 are trapezoidal prisms. The gliding surfaces between the rear wedge elements 11, 12 and 13 are sloped in the z direction only, while the gliding surfaces between the forward wedge elements 13, 14 and 15 are sloped in the x direction only.

In reaction to a compressive force applied by the tightening screw to the outer wedge elements 11 and 15 the wedge-type locking device 10 will expand in both x and z directions as well. However, in relation to the tightening screw the displacement of the second wedge element 12 will be in z direction only, while the displacement of the fourth wedge element 14 will be in x direction only. Each one of the movements is stopped by an abutment upon a surface (not shown) to which a clamping force is to be applied. After both said wedge elements 12 and 14 have abutted the locking device can be locked as described above.

In some cases the embodiment shown in FIGS. 5 and 6 may be preferred because of the additional abutment surfaces provided therein or a reduced number of wedge elements required to provide a given number of abutting surfaces. In other cases, the embodiment of FIGS. 7 and 8 may be preferred because the unidirectional displacement of each one of the wedge elements avoids a sliding movements of the wedge element after abutment in a first one of said x and z directions, as described above.

Those skilled in the art will understand, that the individual wedge elements can provide opposite gliding surfaces facing in said longitudinal direction and providing opposite slopes leading to a symmetric element for example. Alternatively, the slopes of the gliding surfaces of one element can differ in value and/or orientation, see element 13 in FIGS. 7 and 8, for example.

FIG. 9 shows an enlarged perspective view of a preferred embodiment of the tightening screw 41 for use in the embodiments of the present invention shown in the previous figures. The tightening screw comprises a cylindrical shaft section 49 extending within the screw holes formed within the wedge-elements. For a better illustration of the end sections of the tightening screw the long cylindrical midsection has been omitted in the drawing. The forward end provides a cylindrical hand knob 44 configured for manually turning the tightening screw 41 and for projecting out of the fifth wedge element 15 at the forward end thereof, as shown in FIG. 1. The rear end of the shaft section 49 provides a threaded section 45 configured for mating with a nut 46 disposed thereon. The range of the wedge elements 11, 12, 13, 14, 15 (not shown in the figure) are aligned between the hand knob 44 and the nut 46. By rotating the hand knob 44 in relation to the nut 46 the distance between the hand knob and the nut can be shortened and the line of wedge elements located in between can be compressed.

Those with skill in the art will understand that the embodiment shown in FIG. 9 is just an example and other compression means providing the desired result can be found. For example, the nut may be configured for being manually rotated, while the head section of a threaded bold is fixed to the wedge element, instead. Spring means may be provided between the wedge elements and the hand knob and/or the nut for maintaining a compressive force. The nut, the head section and/or the adjacent wedge element may be shaped to positively couple same to prevent a relative rotational movement.

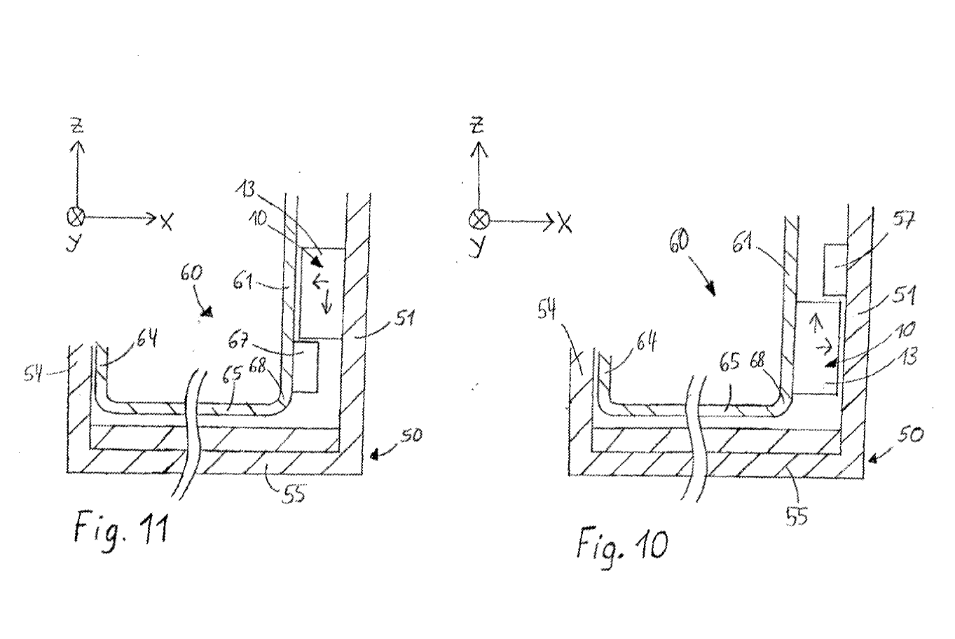

FIG. 10 shows a cross-sectional front elevational view of the preferred embodiment of the present invention shown in FIG. 1. A chassis 60 comprising a right-hand wall 61, a bottom wall 65 and a left-hand wall 64 is located within a tray 50 comprising a right-hand wall 51, a bottom wall 55 and a left-hand wall 54. FIG. 10 shows the identical cross-section of the wedge elements 11, 13, 15 and the directions indicated by arrows in which the wedge-type lock will expand when the second and fourth wedge elements 12 and 14 move in reaction to a compression in y direction. As can be seen from FIG. 10, the expansion in x direction will make the wedge elements 12 and 14 abut on the right-hand tray wall 51 and push the chassis to the left for abutment of the left-hand chassis wall 64 upon the left-hand tray wall 54 to fix the chassis 60 in x direction.

Simultaneously, the expansion will make the wedge elements 12, 14 abut upon a tray bar 57 extending in y direction. Furthermore, the chassis 60 to which one of the wedge elements, say element 13, is fixed, is pressed downwardly for abutment of the chassis bottom wall 65 upon the tray bottom wall 55 to to fix the chassis to the tray 50 in z direction. The chassis 60 has now been clamped in both x and z directions and the compressive force applied by the hand knob 44 and the tightening screw 41 is transformed into clamping forces in both x and z directions.

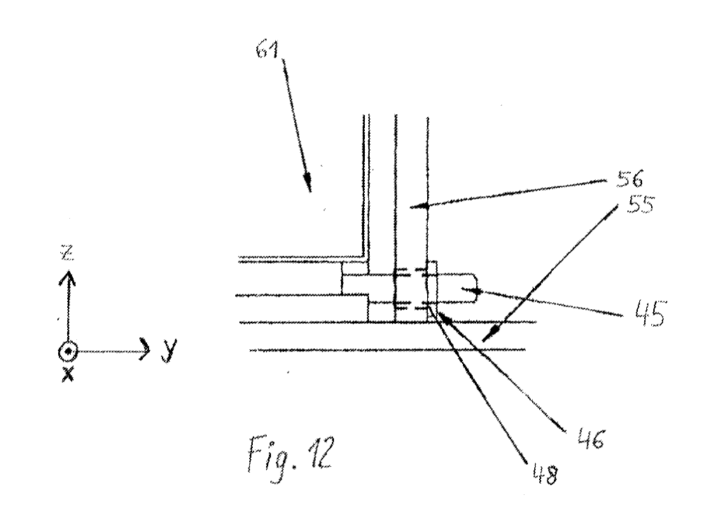

FIG. 11 shows a complimentary embodiment of the present invention as shown in FIG. 10. The wedge-type locking device 10 is structurally the same as that one shown in FIG. 10, but having been rotated around the y axis by 180 degrees. Furthermore, the wedge element 13 (or 11 or 15) has been fixed to the right hand tray wall 51 instead of the right hand chassis wall 61. Consequently, the expansion of the wedge-type lock 10 will now occur to the left and downwardly as indicated by arrows. A chassis bar 67 is extending in y direction and located next to the lower edge 68 for abutment of the wedge elements 12 and 14 thereupon. The expansion in x direction will push the chassis 60 to the left for fixing same as described above. Additionally, the wedge elements 12 and 14 moving downwardly abut on the chassis bar 67 and push the chassis 60 coupled thereto down for abutment of the chassis bottom wall 65 upon the tray bottom wall 55 for fixing the chassis 60 in both x and z directions.

FIG. 12 is an enlarged cross-sectional view of another preferred embodiment of the present invention which is similar to the embodiment shown in FIG. 10 and comprises a wedge-type lock 10 affixed to the chassis 60. The nut 46 at the rear end 45 of the tightening screw 41 is not located just behind the wedge element 11, but the tightening screw 41 extends through a hole 48 formed in the rear tray wall 56 and projects out of the hole 48. The nut 46 is located behind the rear tray wall 56 and contacting same. According to this embodiment, the hand knob 44 and the nut 46 encompass both the wedge elements 11, 12, 13, 14, and 15 and the rear tray wall 56 for applying a compressive force upon all of them when turning the screw 41 in relation to the nut 46. In an alternate embodiment, the nut 46 can be replaced by a female thread section formed within the hole 48 of the rear tray wall 56 for engaging the tightening screw to urge the wedge elements towards the rear tray wall.

Therefore, tightening the tightening screw 41 will not only clamp the wedge-type lock 10 in both x and z directions, but also urge the wedge elements fixing the chassis to the tray in rearward or positive y direction. Therefore, the chassis will be fixed to the tray in y direction as well. The hole 48 may provide a larger cross-sectional area than the tightening screw 41 to allow for some alignment of the tightening screw in x and z directions before tightening the device 10. So the locking device 10 may be positioned in a desired, e.g. central position with regard to adjacent right-hand tray and chassis walls 51 and 61 in x direction or to the tray bottom wall 55 and the tray bar 57 in y direction, for example. Therefore, a subsequent substantially symmetric expansion of the wedge-type lock 10 can be attained and the application of a bending moment to the tightening screw 41 can be substantially reduced or avoided.

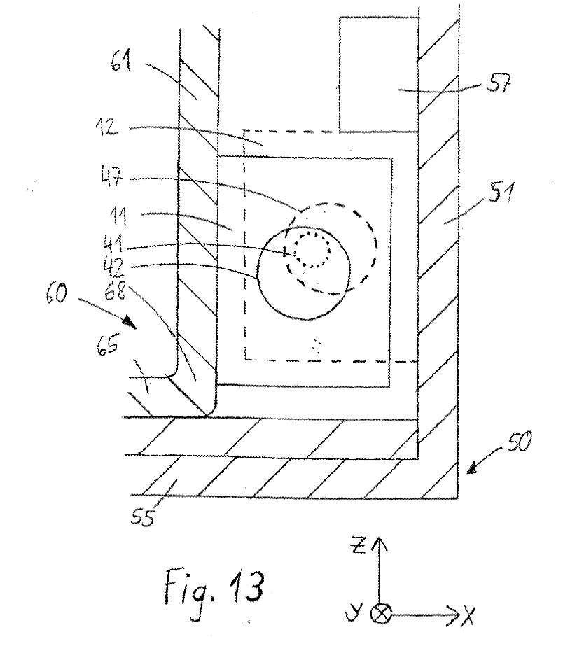

FIG. 13 shows an enlarged cross-sectional view similar to that one shown in FIG. 11 of the preferred embodiment shown in FIG. 12. As described with regard to FIG. 10, the wedge elements 11, 13 and 15 remain in contact to the right-hand tray wall 61, while the wedge elements 12 and 14 are displaced in positive x and z directions in reaction to a compression of the wedge-type lock 10 initiated by tightening the screw 41. The dashed line indicates the abutment position of the wedge elements 12 and 14.

In this embodiment, all wedge elements 11, 12, 13, 14 and 15 provide through holes 42 and 47 large enough to allow for a considerable displacement in both x and z directions in relation to the tightening screw 41 indicated by the dotted circle line. Although the x and z position of the tightening screw 41 may be given by the location of the hole 48 in the rear tray wall 66 the tightening screw is passing through, the wedge elements and chassis are still moveable in x and z directions until abutment of each individual element occurs. Now, the wedge-type lock is clamped in x and z directions by tightening the screw 41. Additionally, tightening the screw couples the wedge-type lock 10 and the chassis 60 mounted thereto to the rear tray wall 56 to attain a fixture in three dimensions.

1. A clamping means, including
a compression means for compressing said clamping means in a longitudinal direction;
said clamping means being expandable in both a first traverse direction and a second traverse direction and being configured for applying clamping forces in both said first and second traverse directions, when said clamping means is compressed by said compression means;
wherein said first traverse direction and said second traverse direction being nonparallel to each other.

2. A clamping fixture including a clamping means according to claim 1, wherein said clamping means is located between a first wall of a fixed element and a first wall of a moveable element for applying clamping forces upon both said fixed and moveable element walls in said first traverse direction to fix said moveable element to said fixed element in said first traverse direction.

3. A clamping fixture according to claim 2, wherein said clamping means is mounted to said moveable element and located in said second traverse direction between a second wall of said fixed element and an abutment element joined to said fixed element for applying clamping forces upon said abutment element in said second traverse direction to fix said moveable element to said fixed element in said second traverse direction.

4. A clamping fixture according to claim 3, wherein said compression means is engaging a third wall of said fixed element and configured for fixing said clamping means to said third wall in said longitudinal direction along with compressing said clamping means.

5. A clamping fixture according to claim 2, wherein said clamping means is mounted to said fixed element and located next to an abutment element joined to said moveable element for applying clamping forces upon said abutment element in said second traverse direction to urge said moveable element to a second wall of said fixed element in said second traverse direction.

6. A clamping means according to claim 1, wherein said longitudinal direction and said first traverse direction being orthogonal.

7. A clamping means according to claim 1, wherein said longitudinal direction and said second traverse direction being orthogonal.

8. A clamping means according to claim 1, wherein said first traverse direction and said second traverse direction being orthogonal.

9. A clamping means according to claim 1, wherein said longitudinal and first and second traverse directions defining a Cartesian coordinate system.

10. A wedge-type locking device comprising a clamping means according to claim 1, said clamping means including
at least two wedge elements including a first and a second wedge elements being aligned to each other in said longitudinal direction, each one of said first and second wedge elements providing at least one gliding surface facing in said longitudinal direction, said gliding surfaces being opposite to and mating with one another,
wherein said compression means is including means for forcing said first and second wedge elements towards one another;
wherein said gliding surfaces of said wedge elements being sloped such that at least two of said wedge elements being urged in said first traverse direction in relation to one another and at least two of said wedge elements being urged in said second traverse direction in relation to one another, when said first and second wedge elements are forced towards one another.

11. Wedge-type locking device according to claim 10, wherein at least one of said gliding surfaces being sloped in both said first and second traverse directions.

12. Wedge-type locking device according to claim 10, wherein at least a first one of said gliding surfaces being sloped in said first traverse direction and at least a second one of said gliding surfaces being sloped in said second traverse direction.

13. Wedge-type locking device according to claim 10, wherein said compression means including a tightening screw for transmitting a pulling force for urging both said first and second wedge elements towards one another.

14. Wedge-type locking device according to claim 13, wherein said tightening screw is received within a through hole extending substantially in said longitudinal direction within at least one of said wedge elements.

15. Wedge-type locking device according to claim 14, wherein both said screw hole and said tightening screw received therein extending within all of said at least two wedge elements.

16. Wedge-type locking device according to claim 14, wherein the cross sectional area of said through hole of at least one wedge element is sized to provide a clearance to allow a movement of said wedge element in relation to said tightening screw in said longitudinal direction.

17. Wedge-type locking device according to claim 14, wherein the cross sectional area of said through hole of at least one wedge element is sized to provide a clearance to allow a movement of said wedge element in relation to said tightening screw in both said longitudinal and first traverse directions.

18. Wedge-type locking device according to claim 14, wherein the cross sectional area of said through hole of at least one wedge element is sized to provide a clearance to allow a movement of said wedge element in relation to said tightening screw in both said longitudinal and second traverse directions.

19. Wedge-type locking device according to claim 14, wherein the cross sectional area of said through hole of at least one wedge element is sized to provide a clearance to allow a movement of said wedge element in relation to said tightening screw in said longitudinal and first and second traverse directions.

20. Wedge-type locking device according to claim 13, wherein said tightening screw comprising an operating means configured to allow manually tightening and releasing said tightening screw and to maintain its setting.

21. Wedge-type locking device according to claim 20, wherein said operating means is a self-locking hand knob.

22. A wedge-type locking device according to claim 13, wherein at least two of said wedge elements being located between a first wall of a tray and a first wall of a chassis for applying clamping forces upon each one of said tray and chassis walls in said first traverse direction to fix said chassis to said tray in said first traverse direction.

23. A wedge-type locking device according to claim 22, wherein at least one of said wedge elements being mounted to said chassis and located in said second traverse direction between a second wall of said tray and an abutment element joined to said tray for making at least one second wedge element apply clamping forces upon said abutment element to fix said chassis to said tray in said second traverse direction.

24. A wedge-type locking device according to claim 23, wherein said tightening screw is engaging a third wall of said tray and being configured for fixing said wedge elements to said third wall in said longitudinal direction along with forcing said wedge elements towards one another.

25. A clamping locking device according to claim 22, wherein at least one of said wedge elements being mounted to said tray and located next to an abutment element joined to said chassis for making at least one second wedge element apply clamping forces upon said abutment element in said second traverse direction to urge said moveable element to a second wall of said tray in said second traverse direction to fix said chassis to said tray in said second traverse direction.
